(19) United States
(12) Patent Application Publication
(10) Pub. No.: US 2025/0267973 A1
(43) Pub. Date: Aug. 21, 2025

(54) PHOTOELECTRIC CONVERSION DEVICE AND METHOD OF MANUFACTURING PHOTOELECTRIC CONVERSION DEVICE

(71) Applicant: CANON KABUSHIKI KAISHA, Tokyo (JP)

(72) Inventor: YUUYA ANDO, Kanagawa (JP)

(21) Appl. No.: 19/046,239

(22) Filed: Feb. 5, 2025

(30) Foreign Application Priority Data
Feb. 15, 2024 (JP) 2024-021144

(51) Int. Cl. H10F 39/00

(52) U.S. Cl. CPC H10F 39/811; H10F 39/018; H10F 39/809

(57) ABSTRACT

A method of manufacturing a photoelectric conversion device includes forming a photoelectric conversion unit in a first substrate, forming a first interconnection on a side of a first face of the first substrate, forming a pinning layer on a second face of the first substrate that is a light receiving face of the photoelectric conversion unit, forming a first opening in the pinning layer, forming an insulating layer on the pinning layer and in the first opening, and forming, in a region inside the first opening in a plan view, a second opening that penetrates the insulating layer and the first substrate and reaches the first interconnection.

### BACKGROUND OF THE INVENTION

### Field of the Invention

The present invention relates to a photoelectric conversion device and a method of manufacturing the photoelectric conversion device.

### Description of the Related Art

In a photoelectric conversion device such as a solid-state imaging device, in order to improve photoelectric conversion efficiency and sensitivity with respect to incident light, a so-called back side irradiated structure has been proposed in which a drive circuit is formed on a front surface side of a semiconductor substrate and a back surface side is used as a light receiving surface. In addition, there has also been proposed a stacked-type photoelectric conversion device in which a circuit substrate on which a drive circuit is formed is prepared separately from a semiconductor substrate on which a photoelectric conversion unit is provided, and the circuit substrate is bonded to a surface of the semiconductor substrate opposite to a light receiving surface. In these photoelectric conversion devices, an opening that penetrates the semiconductor substrate provided with the photoelectric conversion unit and reaches an electrode pad provided on a front surface side of the semiconductor substrate or an interconnection of the circuit substrate may be provided. Japanese Patent Application Laid-Open No. 2013-084763 discloses a solid-state imaging device having a pad opening penetrating the semiconductor substrate from the light-receiving surface side to reach the electrode pad and a through electrode penetrating the semiconductor substrate from the light-receiving surface side to be connected to the interconnection, and a method of manufacturing the same.

However, in the above-described conventional solid-state imaging device and the method of manufacturing the same, a defect may occur due to a process of forming the opening penetrating the semiconductor substrate.

### SUMMARY OF THE INVENTION

An object of the present invention is to provide a technique for facilitating a process of forming an opening penetrating a semiconductor substrate in a photoelectric conversion device having a pad opening penetrating the semiconductor substrate and reaching an electrode pad or having a through electrode penetrating the semiconductor substrate and connected to an interconnection.

According to one disclosure of the present specification, there is provided a method of manufacturing a photoelectric conversion device including forming a photoelectric conversion unit in a first substrate, forming a first interconnection on a side of a first face of the first substrate, forming a pinning layer on a second face of the first substrate that is a light receiving face of the photoelectric conversion unit, forming a first opening in the pinning layer, forming an insulating layer on the pinning layer and in the first opening, and forming, in a region inside the first opening in a plan view, a second opening that penetrates the insulating layer and the first substrate and reaches the first interconnection.

In addition, according to another disclosure of the present specification, there is provided a photoelectric conversion device including a first substrate having a first face and a second face and provided with a photoelectric conversion unit with the second face as a light receiving surface, a first interconnection provided on a side of the first face of the first substrate, a pinning layer provided on the second face of the first substrate and having a first opening, an insulating layer provided on the pinning layer and in the first opening, and a second opening that is provided in a region inside the first opening in a plan view, penetrates the insulating layer and the first substrate, and reaches the first interconnection.

Further features of the present invention will become apparent from the following description of exemplary embodiments with reference to the attached drawings.

### BRIEF DESCRIPTION OF THE DRAWINGS

FIG. 1 is a block diagram illustrating a schematic configuration of a photoelectric conversion device according to a first embodiment.

FIG. 2 is a schematic diagram illustrating a configuration example of the photoelectric conversion device according to the first embodiment.

FIG. 3 is a schematic cross-sectional view illustrating the structure of the photoelectric conversion device according to the first embodiment.

FIG. 4 is a plan view of the periphery of a pad opening of the photoelectric conversion device according to the first embodiment.

FIG. 5A, FIG. 5B, FIG. 5C, FIG. 6A, FIG. 6B, FIG. 7, FIG. 8, FIG. 9, FIG. 10, FIG. 11, and FIG. 12 are cross-sectional views illustrating a method of manufacturing the photoelectric conversion device according to the first embodiment.

FIG. 13 is a schematic cross-sectional view illustrating a structure of a photoelectric conversion device according to a second embodiment.

FIG. 14 and FIG. 15 are cross-sectional views illustrating a method of manufacturing the photoelectric conversion device according to the second embodiment.

FIG. 16 is a schematic cross-sectional view illustrating a structure of a photoelectric conversion device according to a third embodiment.

FIG. 17 is a plan view of the periphery of a pad opening of the photoelectric conversion device according to the third embodiment.

FIG. 18 is a block diagram illustrating a schematic configuration of a photoelectric conversion system according to a fourth embodiment.

FIG. 19A is a diagram illustrating a configuration example of a photoelectric conversion system according to a fifth embodiment.

FIG. 19B is a diagram illustrating a configuration example of a movable object according to the fifth embodiment.

FIG. 20 is a block diagram illustrating a schematic configuration of an equipment according to a sixth embodiment.

### DESCRIPTION OF THE EMBODIMENTS

Preferred embodiments of the present invention will now be described in detail in accordance with the accompanying drawings.

### First Embodiment

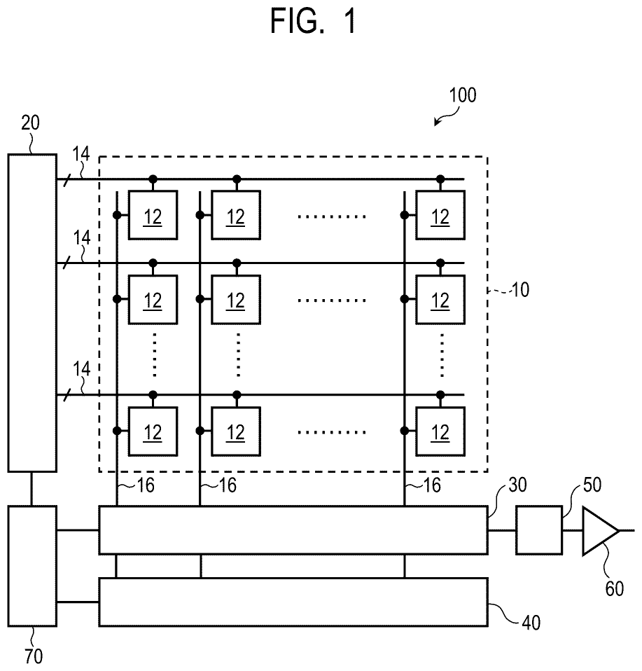

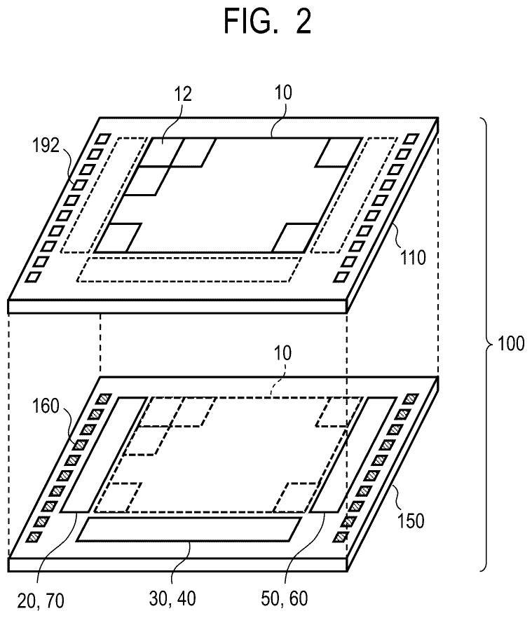

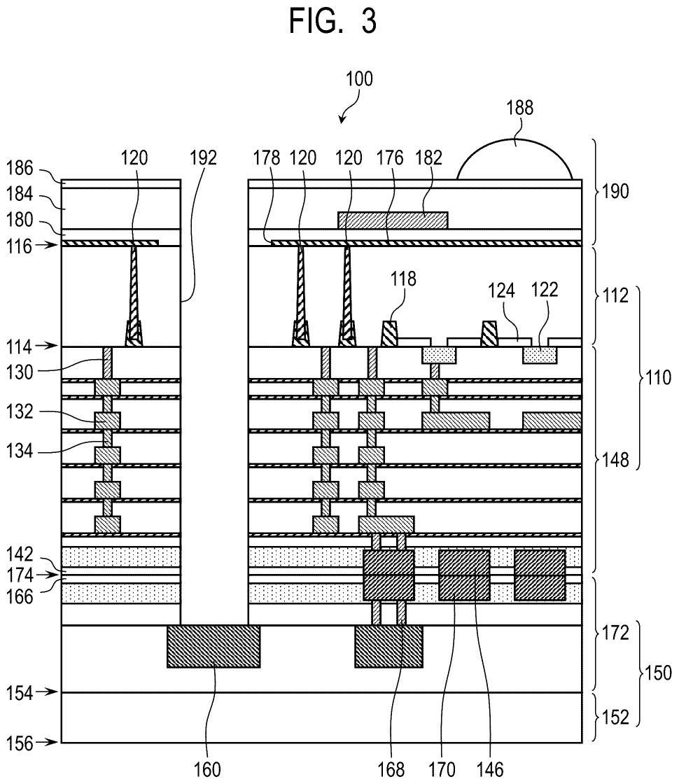

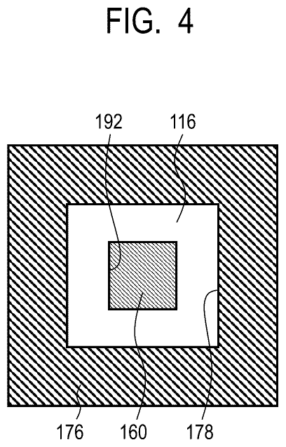

A photoelectric conversion device according to a first embodiment of the present invention will be described with reference to FIG. 1 to FIG. 4. FIG. 1 is a block diagram illustrating a schematic configuration of a photoelectric conversion device according to the present embodiment. FIG. 2 is a perspective view illustrating a configuration example of the photoelectric conversion device according to the present embodiment. FIG. 3 is a schematic cross-sectional view illustrating the structure of the photoelectric conversion device according to the present embodiment. FIG. 4 is a plan view of the periphery of the pad opening of the photoelectric conversion device according to the present embodiment.

The photoelectric conversion device 100 according to the present embodiment may include, as illustrated in, e.g., FIG. 1, a pixel region 10, a vertical scanning circuit unit 20, a readout circuit unit 30, a horizontal scanning circuit unit 40, a signal processing circuit unit 50, an output circuit unit 60, and a control circuit unit 70.

In the pixel region 10, a plurality of pixels 12 arranged in a matrix over a plurality of rows and a plurality of columns are provided. Each pixel 12 includes a photoelectric conversion element such as a photodiode, and outputs a pixel signal according to the amount of incident light. The number of rows and the number of columns of the pixel array arranged in the pixel region 10 are not particularly limited. In addition to an effective pixel that outputs a pixel signal according to the amount of incident light, an optical black pixel in which a photoelectric conversion unit is shielded, a dummy pixel that does not output a signal, or the like may be disposed in the pixel region.

In each row of the pixel array constituting the pixel region 10, a control line 14 is arranged so as to extend in a first direction (lateral direction in FIG. 1). Each of the control lines 14 is connected to the pixels 12 arranged in the first direction on the corresponding row and forms a signal line common to these pixels 12. The first direction in which the control lines 14 extend may be referred to as a row direction or a horizontal direction. The control line 14 is connected to the vertical scanning circuit unit 20. Each row of control lines 14 may include a plurality of signal lines.

In each column of the pixel array constituting the pixel region 10, an output line 16 is arranged so as to extend in a second direction (vertical direction in FIG. 1) intersecting the first direction. Each of the output lines 16 is connected to the pixels 12 arranged in the second direction on the corresponding column and forms a signal line common to these pixels 12. The second direction in which the output lines 16 extend may be referred to as a column direction or a vertical direction. The output line 16 is connected to the readout circuit unit 30.

The vertical scanning circuit unit 20 has a function of generating a control signal for driving the pixels 12 in response to a control signal from the control circuit unit 70 and outputting the generated control signal to the pixels 12 via the control lines 14. A logic circuit such as a shift register or an address decoder may be used as the vertical scanning circuit unit 20. The vertical scanning circuit unit 20 sequentially outputs control signals to the control lines 14 of each row, thereby sequentially driving the pixels 12 of the pixel region 10 row by row. The signals read out from the pixels 12 in units of rows are input in parallel to the readout circuit unit 30 via the output lines 16 arranged in each column of the pixel region 10.

The readout circuit unit 30 has a function of performing predetermined signal processing on the pixel signal output from the pixel 12 via the output line 16 and holding the processed pixel signal in a memory for each column. Examples of the signal processing performed by the readout circuit unit 30 include amplification processing and analog-to-digital (AD) conversion processing.

The horizontal scanning circuit unit 40 has a function of generating a control signal for reading out a pixel signal from the memory of each column of the readout circuit unit 30 in response to a control signal from the control circuit unit 70 and outputting the generated control signal to the readout circuit unit 30. The horizontal scanning circuit unit 40 sequentially outputs control signals to the memories of the respective columns of the readout circuit unit 30 and sequentially outputs the pixel signals held in the memories of the respective columns to the signal processing circuit unit 50. A logic circuit such as a shift register or an address decoder may be used as the horizontal scanning circuit unit 40.

The signal processing circuit unit 50 has a function of performing predetermined signal processing on a signal output from the readout circuit unit 30. Examples of the processing executed by the signal processing circuit unit 50 include amplification processing and digital correlated double sampling (CDS) processing.

The output circuit unit 60 has a function of outputting the signal processed by the signal processing circuit unit 50 to the outside of the photoelectric conversion device 100. The external interface circuit included in the output circuit unit 60 is not particularly limited. As the external interface circuit, for example, a SerDes (SERializer/DESerializer) transmission circuit may be applied. The SerDes transmission circuit is, for example, a low voltage differential signaling (LVDS) circuit or a scalable low voltage signaling (SLVS) circuit.

The control circuit unit 70 has a function of supplying control signals for controlling operations and timings of the vertical scanning circuit unit 20, the readout circuit unit 30, and the horizontal scanning circuit unit 40. Note that not all of these control signals are necessarily supplied from the control circuit unit 70, and at least a part of these control signals may be supplied from the outside of the photoelectric conversion device 100.

The photoelectric conversion device 100 according to the present embodiment may have a configuration in which all the functional blocks described above are disposed on one substrate or may have a configuration as a stacked-type photoelectric conversion device in which the functional blocks described above are separately formed on a plurality of substrates and these substrates are bonded and electrically connected. In the present embodiment, as illustrated in, e.g., FIG. 2, the photoelectric conversion device 100 is configured by stacking and bonding two substrates (the first substrate 110 and the second substrate 150). However, the number of substrates constituting the photoelectric conversion device 100 is not necessarily limited to two and may be three or more.

The first substrate 110 may be provided with, for example, a plurality of pixels 12 constituting the pixel region 10 among the functional blocks described above. The second substrate 150 may be provided with, for example, other functional blocks excluding the plurality of pixels 12 in the pixel region 10 among the above-described functional blocks. By arranging the pixel 12 and the other constituent elements on different substrates, it is possible to reduce the size and increase the functionality of the photoelectric conversion device 100 without sacrificing the light receiving area of the pixel 12.

A plurality of electrode pads 160 for electrical connection between the photoelectric conversion device 100 and an external power supply or another device is provided on a peripheral portion of the second substrate 150. The first substrate 110 is provided with pad openings 192 for exposing the electrode pads 160 when the first substrate 110 is stacked on the second substrate 150. In this case, the electrical connection from the outside to the electrode pad 160 is performed through the pad opening 192.

Next, a more detailed structure of the photoelectric conversion device 100 according to the present embodiment will be described with reference to FIG. 3 and FIG. 4.

As illustrated in FIG. 3, the photoelectric conversion device 100 includes a first substrate 110 and a second substrate 150. The first substrate 110 includes a semiconductor substrate 112 having a first face 114 and a second face 116, and an interconnection structure layer 148 provided on the first face 114. The first face 114 is a front surface of the semiconductor substrate 112 on which predetermined elements such as transistors and photodiodes are provided. The second substrate 150 includes a semiconductor substrate 152 having a first face 154 and a second face 156, and an interconnection structure layer 172 provided on the first face 154. The first face 154 is a front surface of the semiconductor substrate 152 on which predetermined elements such as transistors are provided. The first substrate 110 and the second substrate 150 are bonded face-to-face so that the first face 114 and the first face 154 face each other. An interface between the interconnection structure layer 148 and the interconnection structure layer 172 is a bonding face 174 between the first substrate 110 and the second substrate 150.

The semiconductor substrate 112 is obtained by thinning a semiconductor substrate made of, for example, a single crystalline silicon. A plurality of pixels 12 constituting the pixel region 10 may be provided on the semiconductor substrate 112. Each of the plurality of pixels 12 includes a photoelectric conversion element such as a photodiode, and transistors for controlling an exposure period of the photoelectric conversion element and readout of a signal based on charge generated by the photoelectric conversion element. These elements are provided on the first face 114 side of the semiconductor substrate 112. FIG. 3 illustrates a transistor having a gate electrode 122 and impurity regions 124 serving as source/drain regions as an example of an element constituting the pixel 12. Isolation structures 118 and 120 are provided in the semiconductor substrate 112. The isolation structure 118 has a function of separating elements from each other. The isolation structure 120 is provided so as to penetrate the semiconductor substrate 112 integrally with the isolation structure 118 and has a role of separating an element forming region of the semiconductor substrate 112 from the outside.

An interconnection structure layer 148 in which a plurality of interconnection layers is arranged in an insulating layer is provided on the first face 114 of the semiconductor substrate 112. FIG. 3 illustrates a multi-level interconnection including six interconnection layers as the interconnection structure layer 148. The first to fifth interconnection layers from the side of the semiconductor substrate 112 include the interconnection 132. The interconnection layer of the uppermost layer (sixth interconnection layer) farthest from the semiconductor substrate 112 includes the interconnection 146. The interconnection 132 of the first interconnection layer is electrically connected to the semiconductor substrate 112 and the gate electrode 122 via the contact via 130. Interconnections 132 of different levels and interconnections 132 and interconnections 146 are electrically connected to each other via interconnection vias 134. The number of interconnection layers constituting the interconnection structure layer 148 is not limited to six and may be appropriately increased or decreased. The interconnections 132 and 146 may be formed of a conductive film mainly made of a metal material such as copper or aluminum. The uppermost surface of the interconnection structure layer 148 is constituted by the insulating layer 142 and the interconnection 146. The uppermost surface serves as a bonding face 174 with the second substrate 150.

The semiconductor substrate 152 is a semiconductor substrate made of, for example, a single crystalline silicon. As described above, drive circuits such as the vertical scanning circuit unit 20, the readout circuit unit 30, the horizontal scanning circuit unit 40, the signal processing circuit unit 50, the output circuit unit 60, and the control circuit unit 70 may be provided on the semiconductor substrate 152. The elements constituting these circuits are provided on the first face 154 side of the semiconductor substrate 152. In FIG. 3, these elements are omitted for simplification of the drawing.

An interconnection structure layer 172 in which a plurality of interconnection layers is arranged in an insulating layer is provided on the first face 154 of the semiconductor substrate 152. In FIG. 3, in order to simplify the drawing, an interconnection layer including the electrode pad 160 and an uppermost interconnection layer including the interconnection 170 are illustrated among the interconnection layers constituting the interconnection structure layer 172. The number of interconnection layers constituting the interconnection structure layer 172 is not particularly limited. Interconnections of different levels are electrically connected to each other via interconnection vias 168. The interconnection 170 and the electrode pad 160 may be formed of a conductive film mainly made of a metal material such as copper or aluminum. The uppermost surface of the interconnection structure layer 172 is constituted by the insulating layer 166 and the interconnection 170. The uppermost surface serves as a bonding face 174 with the first substrate 110.

On the second face 116 of the semiconductor substrate 112, a pinning layer 176, an insulating layer 180, a light shielding film 182, a planarization layer 184, an insulating layer 186, and a microlens 188 are provided in this order. The pinning layer 176 has a function of suppressing a dark current via a defect (interface level) of the surface portion of the semiconductor substrate 112, and may be formed of, for example, aluminum oxide (Al₂O₃), tantalum oxide (Ta₂O₅), or the like. The light shielding film 182 has an opening in a portion corresponding to the pixel region 10. The light shielding film 182 may be electrically connected to the semiconductor substrate 112 via an interconnection via (not illustrated). A trench pattern may be formed in the planarization layer 184 to form a light shielding portion for performing pixel separation as required. Light to be detected by the photoelectric conversion element of the pixel 12 enters from the second face 116 side of the semiconductor substrate 112 through the microlens 188. That is, the photoelectric conversion device 100 according to the present embodiment is a back-illuminated photoelectric conversion device in which the side of the back surface (the second face 116) of the semiconductor substrate 112 is a light-receiving surface. Note that, in this specification, for convenience, a stacked structure body from the insulating layer 180 to the microlens 188 may be referred to as an optical structure layer 190. The optical structure layer 190 may further include other optical members such as color filters.

In a region where the electrode pad 160 is disposed in a plan view, a pad opening 192 is provided which penetrates the insulating layer 186, the planarization layer 184, the insulating layer 180, the semiconductor substrate 112, the interconnection structure layer 148, and a part of the interconnection structure layer 172 and reaches the electrode pad 160. The pinning layer 176 has an opening 178 in a region where the electrode pad 160 is disposed in the plan view. FIG. 4 is a plan view of the electrode pad 160, the pad opening 192, the pinning layer 176, and the opening 178 projected onto a plane parallel to the second face 116 of the semiconductor substrate 112. As illustrated in FIG. 4, the pinning layer 176 has an opening 178 having an opening width larger than that of the pad opening 192. In the plan view, the pad opening 192 is located inside the opening 178. In other words, the pinning layer 176 is not exposed to the inner wall portion of the pad opening 192. Note that in this specification, a plan view refers to a view from a normal direction of the semiconductor substrates 112 and 152.

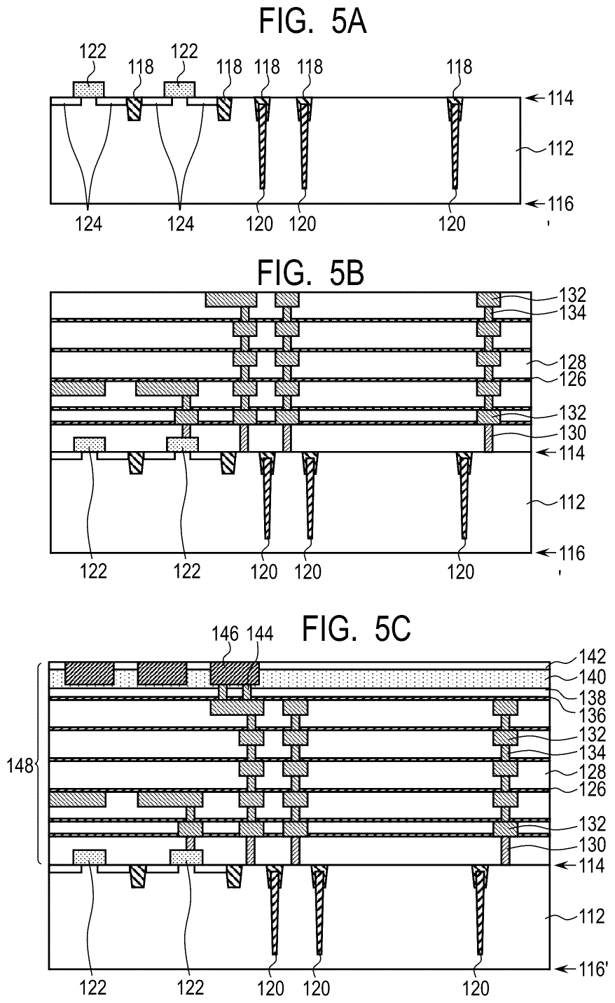

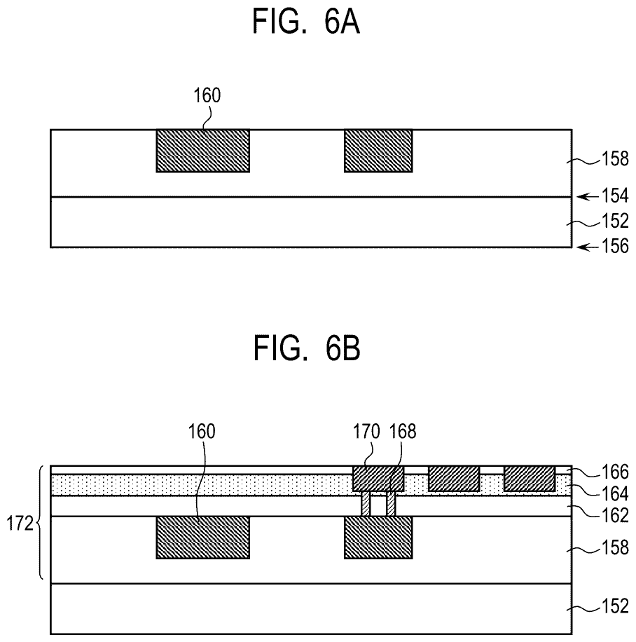

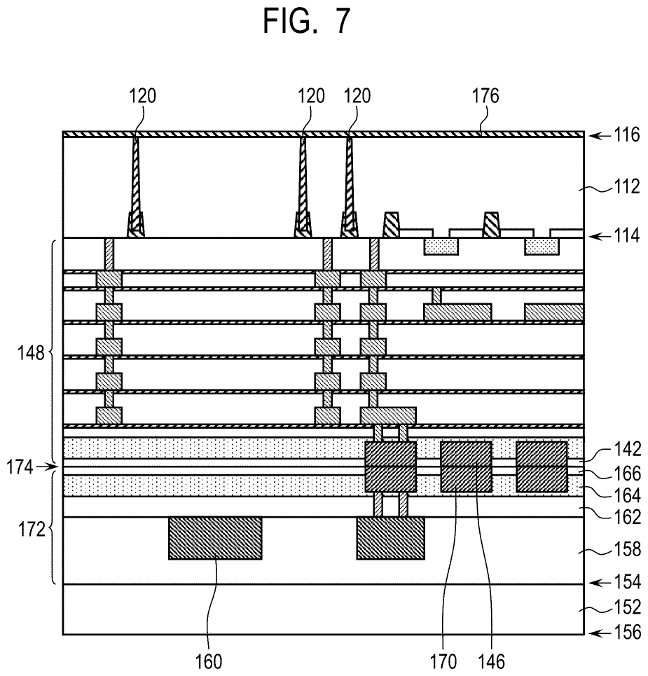

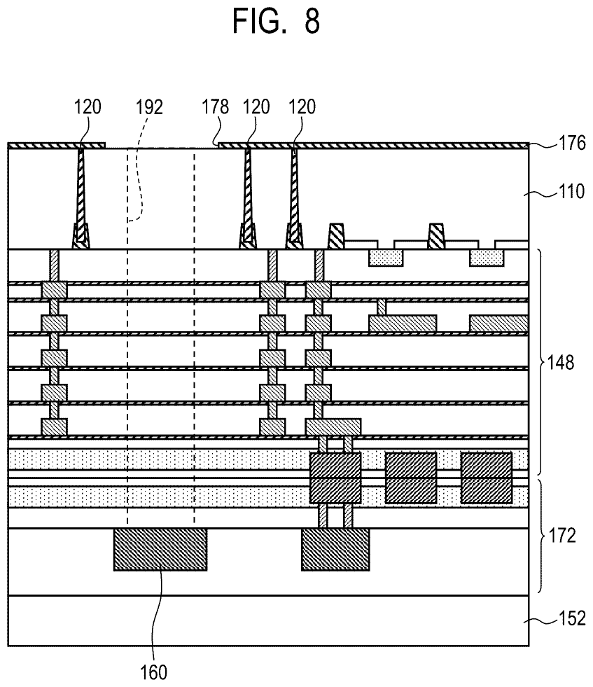

Next, a method of manufacturing the photoelectric conversion device according to the present embodiment will be described with reference to FIG. 5A to FIG. 12. FIG. 5A to FIG. 12 are cross-sectional views illustrating the method of manufacturing the photoelectric conversion device according to the present embodiment.

First, a semiconductor substrate 112 having a first face 114 and a second face 116′ is prepared as a base material of the first substrate 110. Then, an isolation structure 118 for separating elements from each other is formed on the first face 114 side of the semiconductor substrate 112 by, for example, a shallow trench isolation (STI) method. An isolation structure 120 for separating the element forming region of the semiconductor substrate 112 from the outside is formed by, for example, a deep trench isolation (DTI) method as required. The isolation structure 120 is disposed so as to surround the pad opening 192 and the element formation region of the semiconductor substrate 112 in the plan view.

Next, predetermined elements constituting the pixel region 10, such as photodiodes as the photoelectric conversion units and pixel transistors, are formed in the active region of the semiconductor substrate 112 defined by the isolation structure 118 (FIG. 5A). FIG. 5A illustrates, as an example of these elements, two transistors each having a gate electrode 122 and impurity regions 124 serving as source/drain regions.

Next, the formation of the interlayer insulating layer and the formation of the interconnection layer are repeatedly performed over the first face 114 of the semiconductor substrate 112 on which the isolation structures 118 and 120 and the predetermined elements are provided, and a multi-level interconnection layer including, for example, five interconnection layers is formed (FIG. 5B). The interconnections 132 constituting each interconnection layer may be made of, for example, copper (Cu) or aluminum (Al). The interlayer insulating layer may be formed of a stacked film of an insulating layer 126 made of, for example, silicon carbide and an insulating layer 128 made of, for example, silicon oxide. When the interconnections 132 are made of, for example, copper, the insulating layer 126 may function as a diffusion prevention film that prevents diffusion of copper. The first-level interconnections 132 may be electrically connected to the semiconductor substrate 112 or the gate electrode 122 through the contact vias 130. The first to fifth-level interconnection layers may be electrically connected to each other via the interconnection vias 134.

Next, an interlayer insulating layer and a sixth-level interconnection layer are formed on the interlayer insulating layer in which the fifth-level interconnections 132 are disposed. The interconnections 146 constituting the sixth-level interconnection layer may be made of, for example, copper. The interlayer insulating layer may be formed of a stacked film of an insulating layer 136 made of, for example, silicon carbide, an insulating layer 138 made of, for example, silicon oxide, an insulating layer 140 made of, for example, silicon nitride, and an insulating layer 142 made of, for example, silicon oxide. The insulating layer 142 may have a function as a protective film that suppresses entry of moisture or the like. The insulating layer 142 forms a bonding portion with the second substrate 150 together with the interconnections 146. For this purpose, the uppermost surface of the first substrate 110 is constituted by the insulating layer 142 and the interconnections 146. The interconnections 146 may be electrically connected to the lower-level interconnection layers via the interconnection vias 144.

Thus, an interconnection structure layer 148 including a total of six interconnection layers is formed on the first face 114 of the semiconductor substrate 112 (FIG. 5C). Although FIG. 5C exemplifies the interconnection structure layer 148 including six interconnection layers, the number of interconnection layers constituting the interconnection structure layer 148 is not limited to six and may be appropriately increased or decreased.

A semiconductor substrate 152 having a first face 154 and a second face 156 is prepared as a base material of the second substrate 150 separately from the first substrate 110. Then, on the side of the first face 154 of the semiconductor substrate 152, elements (not illustrated) constituting a predetermined circuit and an insulating layer 158 provided with an interconnection layer including the electrode pad 160 are formed (FIG. 6A). Although FIG. 6A illustrates only the insulating layer 158 and one interconnection layer disposed therein, two or more interconnection layers may be disposed in the insulating layer 158. In FIG. 6A, it is assumed that the electrode pad 160 is formed of the uppermost interconnection layer among the interconnection layers disposed in the insulating layer 158, but the electrode pad 160 does not necessarily need to be formed of the uppermost interconnection layer.

Next, an interlayer insulating layer and an interconnection layer disposed therein are formed on the insulating layer 158 provided with the interconnection layer including the electrode pad 160. The interconnections 170 constituting the interconnection layer in the insulating layer 153 may be made of, for example, copper. The interlayer insulating layer may be formed of a stacked film of an insulating layer 162 made of, for example, silicon oxide, an insulating layer 164 made of, for example, silicon nitride, and an insulating layer 166 made of, for example, silicon oxide. The insulating layer 164 may function as a protective film that suppresses entry of moisture or the like. The insulating layer 166 forms a bonding portion with the first substrate 110 together with the interconnections 170. For this purpose, the uppermost surface of the second substrate 150 is constituted by the insulating layer 166 and the interconnections 170. The interconnections 170 may be electrically connected to a lower-level interconnection layers via interconnection vias 168.

Thus, the interconnection structure layer 172 including the electrode pad 160 and the interconnections 170 is formed on the first face 154 of the semiconductor substrate 152 (FIG. 6B).

Next, the first substrate 110 and the second substrate 150 manufactured in this manner are bonded to each other by a face-to-face bonding technique so that the side of the first face 114 of the semiconductor substrate 112 and the side of the first face 154 of the semiconductor substrate 152 face each other. Thus, at the bonding face 174 between the first substrate 110 and the second substrate 150, the insulating layer 142 and the insulating layer 166 are in contact with each other, and the interconnections 146 and the interconnections 170 are in contact with each other, and the first substrate 110 and the second substrate 150 are physically and electrically bonded to each other.

Next, the semiconductor substrate 112 is polished and thinned from the second face 116′ side by, for example, the chemical mechanical polishing (CMP) method. The surface exposed by polishing the second face 116′ of the semiconductor substrate 112 is a new second face 116. The semiconductor substrate 112 is preferably thinned until the second face 116 reaches the isolation structure 120.

Next, a pinning layer 176 made of, for example, an aluminum oxide film and/or a tantalum oxide film is formed on the second face 116 of the semiconductor substrate 112 by, for example, a sputtering method or a chemical vapor deposition (CVD) method (FIG. 7).

Next, the pinning layer 176 is patterned using a photolithography technique and an etching technique to form an opening 178 in a portion corresponding to a region (indicated by a dotted line in FIG. 8) where the pad opening 192 is to be formed (FIG. 8). In this case, the opening 178 is formed to have an opening width larger than that of the pad opening 192 so that the entire pad opening 192 is positioned inside the opening 178 even when the maximum alignment deviation occurs in the pad opening 192 in consideration of the alignment tolerance at the time of forming the pad opening 192.

Although FIG. 8 illustrates a case where the etching of the opening 178 is stopped on the surface (the second face 116) of the semiconductor substrate 112, the etching of the opening 178 may be continued until at least a part of the semiconductor substrate 112 is removed.

Next, an insulating material such as silicon oxide is deposited by, e.g., CVD method, and the surface thereof is planarized by, e.g., CMP method to form an insulating layer 180 made of silicon oxide or the like (FIG. 9).

Next, a light-shielding material, for example, a metal material such as aluminum is deposited by, for example, a sputtering method, and then patterned by using a photolithography technique and an etching technique to form a light shielding film 182 (FIG. 10).

Next, an insulating material such as silicon oxide is deposited by, for example, CVD method, and then the surface thereof is planarized by, for example, CMP method to form a planarization layer 184 made of silicon oxide or the like. Next, an insulating material such as silicon oxide is deposited by, e.g., CVD method to form an insulating layer 186 made of silicon oxide or the like. Next, a microlens 188 is formed on the insulating layer 186 (FIG. 11).

Next, a photoresist (not illustrated) having an opening in a region where the pad opening 192 is to be formed is formed by photolithography. Next, using this photoresist as a mask, the insulating layer 186, the planarization layer 184, the insulating layer 180, the interconnection structure layer 148, and a part of the interconnection structure layer 172 are etched in order to form the pad opening 192 reaching the electrode pad 160. At this time, the region where the pad opening 192 is to be formed is located inside the opening 178 of the pinning layer 176, and it is not necessary to remove the pinning layer 176 in the process of forming the pad opening 192. Thereafter, the photoresist used as the mask is removed to complete the photoelectric conversion device of the present embodiment (FIG. 11).

In the present embodiment, the opening 178 is formed in advance in the pinning layer 176 before the pad opening 192 is formed. This is to solve the following problems that may occur when the pad opening 192 is opened.

The first problem is that, since the etching selectivity between the pinning layer 176 and the photoresist used in forming the pad opening 192 is small, the photoresist may disappear when the pinning layer 176 is etched in the process of forming the pad opening 192. When the photoresist disappears, the opening area of the pad opening 192 may be larger than the opening area on the resist pattern. Further, there is a possibility that the opening shape is changed from the expected shape and a portion which should not be etched is etched. In order to avoid these problems, it is necessary to increase the thickness of the photoresist, but when the thickness of the photoresist is increased, the aspect ratio of the photoresist particularly between the pad openings 192 is increased, which may cause collapse of the photoresist.

The second problem is that when the pinning layer 176 is etched in the process of forming the pad opening 192, a deposition component generated at the time of etching the pinning layer 176 and a deposition component generated at the time of etching the planarization layer 184 are mixed and peeling and removal in a subsequent process becomes difficult. In order to avoid this, it is necessary to perform a peeling and removing step at the time when the etching of the planarization layer 184 is completed. However, since the photoresist is also removed when the peeling and removing step is performed, it is necessary to form the photoresist used for etching the pad opening 192 again in the peeling and removing step. In this case, disadvantages such as an increase in the number of steps and deterioration in alignment accuracy at the time of patterning may occur.

The third problem is that when the pinning layer 176 is etched in the process of forming the pad opening 192, the side wall of the pinning layer 176 is inclined in the selective etching by the dry etching, and the opening area of the pad opening 192 becomes smaller than the opening area of the resist pattern.

In this regard, in the present embodiment, since the opening 178 is formed in advance in the pinning layer 176 before the pad opening 192 is formed, these problems do not occur. Therefore, according to the present embodiment, the photoresist used to form the pad opening 192 may be made thin, and the peeling process in the subsequent step is also facilitated. Avoiding the third problem is particularly effective when the opening area of the pad opening 192 is reduced.

As described above, according to the present embodiment, in the photoelectric conversion device including the pad opening penetrating the semiconductor substrate and reaching the electrode pad, the process of forming the opening penetrating the semiconductor substrate from the back surface side may be facilitated.

### Second Embodiment

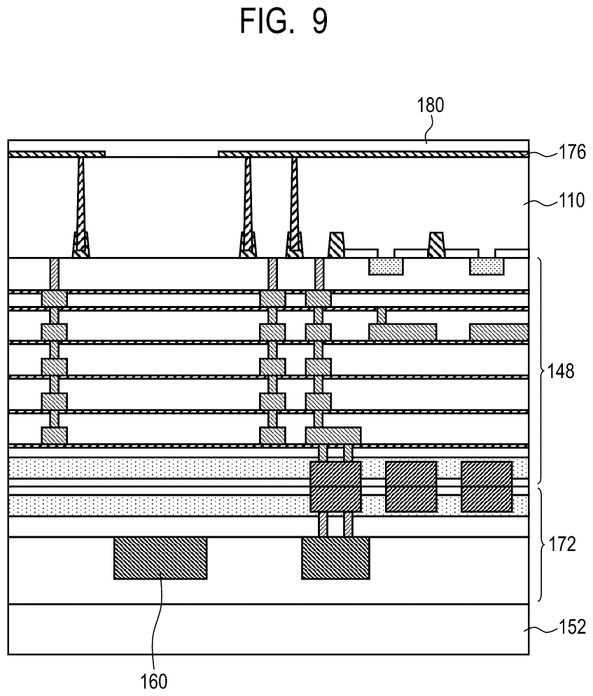

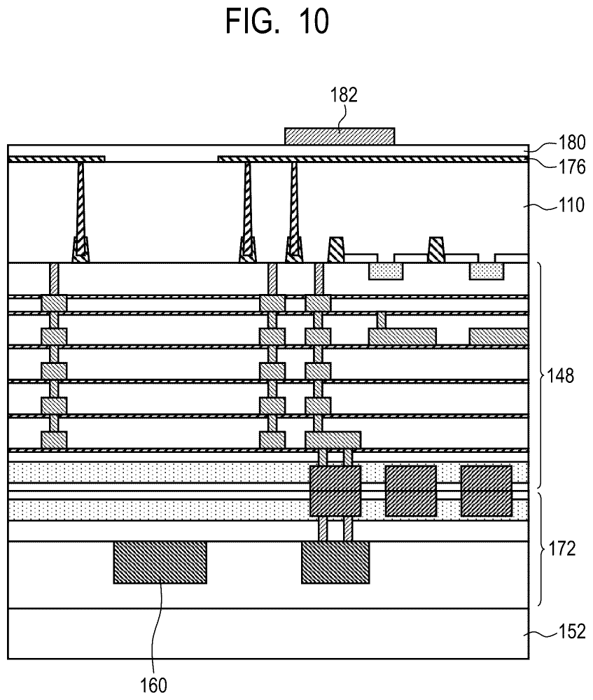

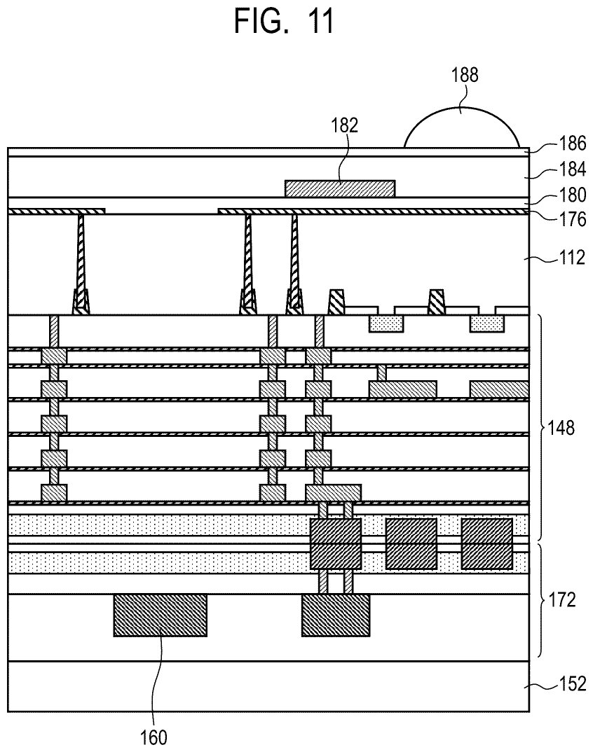

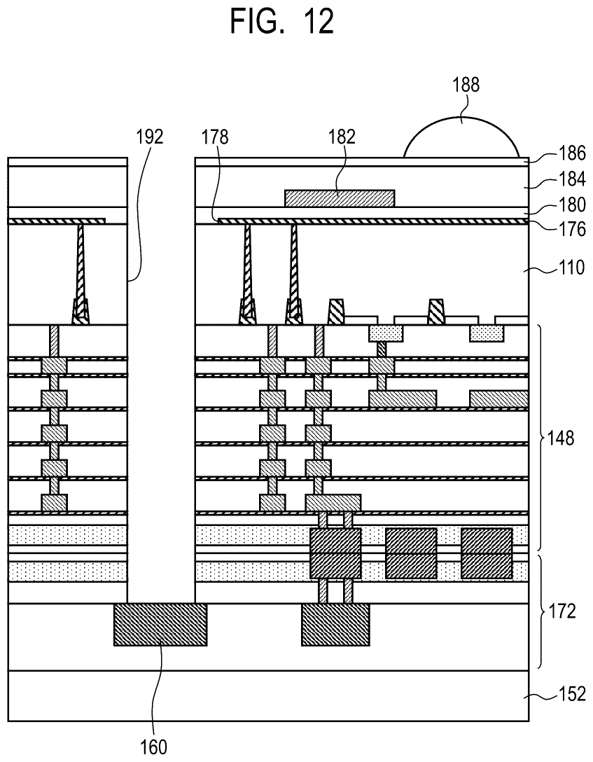

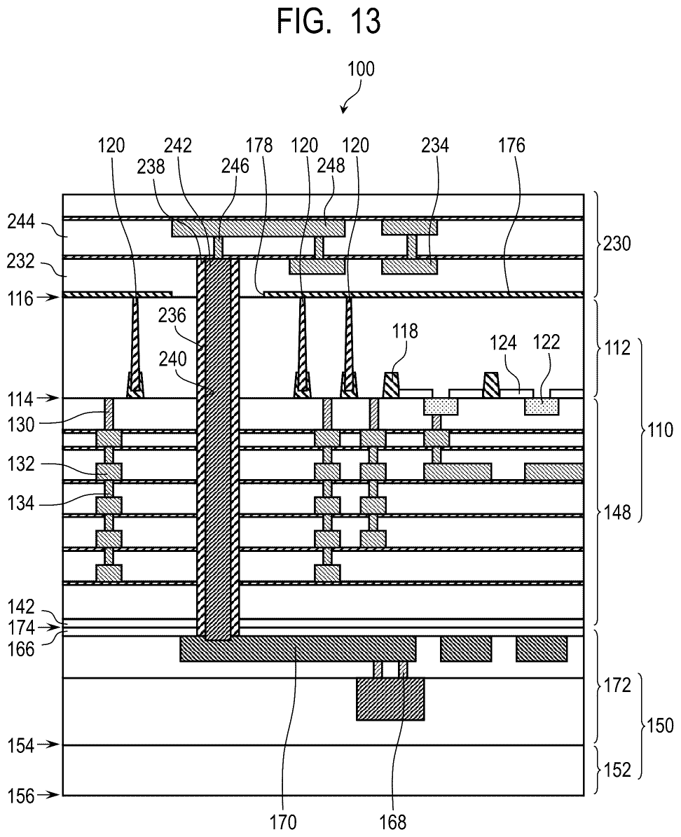

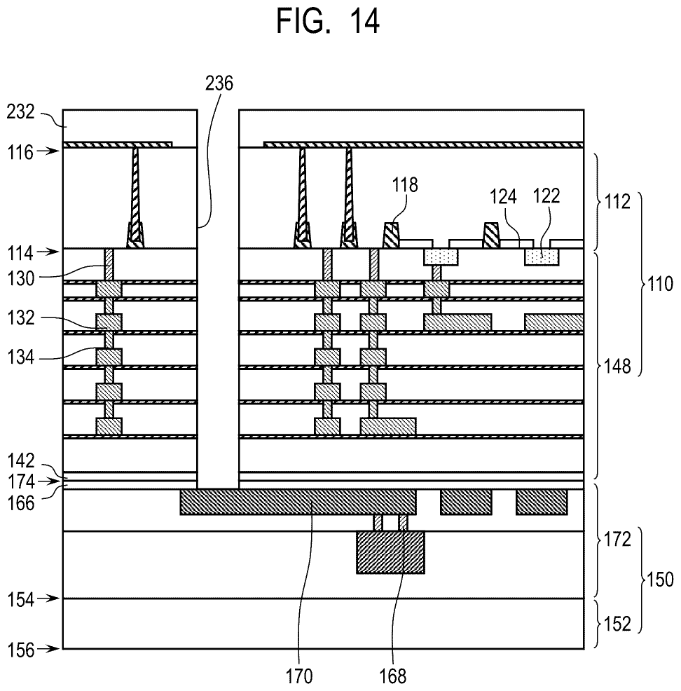

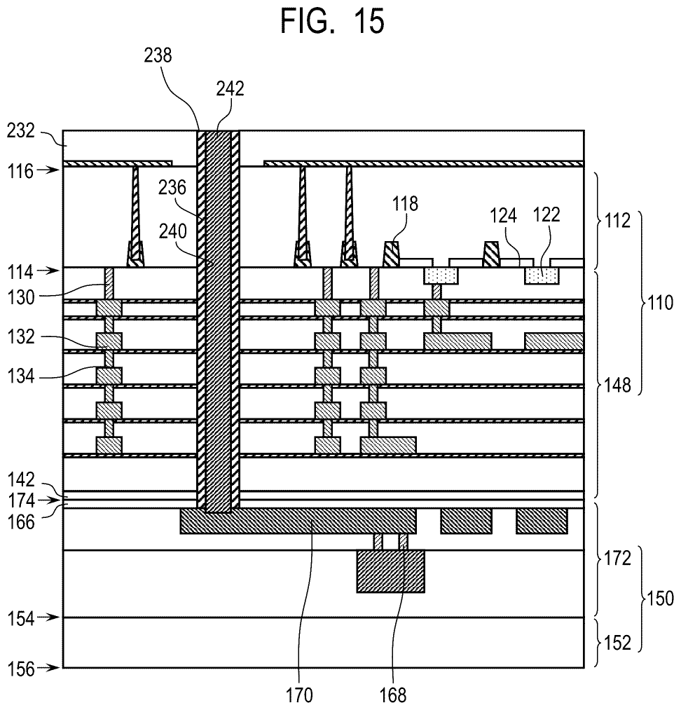

A photoelectric conversion device and a method of manufacturing the same according to a second embodiment of the present invention will be described with reference to FIG. 13 to FIG. 15. The same components as those of the photoelectric conversion device according to the first embodiment are denoted by the same reference numerals, and description thereof will be omitted or simplified. FIG. 13 is a schematic cross-sectional view illustrating the structure of the photoelectric conversion device according to the present embodiment. FIG. 14 and FIG. 15 are cross-sectional views illustrating the method of manufacturing the photoelectric conversion device according to the present embodiment.

In the first embodiment, the structure and the manufacturing method suitable for forming the pad opening 192 of the stacked-type photoelectric conversion device have been described, but the same structure and manufacturing method may also be applied to a through electrode. In the present embodiment, an application example to a stacked-type photoelectric conversion device including a through electrode will be described.

As illustrated in FIG. 13, the photoelectric conversion device 100 according to the present embodiment is similar to the photoelectric conversion device according to the first embodiment in that the first substrate 110 and the second substrate 150 are bonded to each other in a face-to-face manner. The interconnection structure layer 230 is provided on the second face 116 side of the semiconductor substrate 112 via the pinning layer 176. The interconnection structure layer 230 includes an insulating layer 232, an interconnection layer including interconnections 234 disposed in the insulating layer 232, an insulating layer 244 disposed on the insulating layer 232, and an interconnection layer including interconnections 248 disposed in the insulating layer 244. The interconnections 234 and the interconnections 248 are electrically connected to each other through the interconnection vias 246. The optical structure layer 190 (not illustrated in FIG. 13) may be provided over the interconnection structure layer 230.

The bonding face 174 between the first substrate 110 and the second substrate 150 is formed by bonding between the insulating layer 142 provided on the uppermost surface of the interconnection structure layer 148 and the insulating layer 166 provided on the uppermost surface of the interconnection structure layer 172. That is, the uppermost interconnections 170 of the interconnection structure layer 172 do not form the bonding face 174.

The interconnection 170 and the interconnection 248 are electrically connected to each other via an interconnection via 246 and a through electrode 242 provided so as to penetrate the insulating layer 232, the first substrate 110, and the insulating layer 166. The through electrode 242 and the first substrate 110 are insulated from each other by an insulating layer 238 provided in an inner wall portion of the opening 236 in which the through electrode 242 is disposed.

When the through electrode 242 is provided as in the photoelectric conversion device 100 according to the present embodiment, the opening 236 in which the through electrode 242 is disposed is provided so as to penetrate through the stacked body including the pinning layer 176, as in the case of the pad opening 192 of the first embodiment. That is, the opening 236 is formed by sequentially etching the constituent members up to the interconnection 170 after forming the pinning layer 176 and the insulating layer 232 over the second face 116 of the first substrate 110. Therefore, when the etching of the pinning layer 176 is included in the series of etching steps, a problem similar to the problem described in the first embodiment may occur. Therefore, also in the present embodiment, after the pinning layer 176 is formed and before the insulating layer 232 is formed, the opening 178 is formed in advance in the region of the pinning layer 176 where the opening 236 is to be formed.

FIG. 14 and FIG. 15 correspond to cross-sectional views after the process corresponding to FIG. 7 of the first embodiment. First, a pinning layer 176 made of, for example, an aluminum oxide film and/or a tantalum oxide film is formed on the second face 116 of the semiconductor substrate 112 exposed by polishing by, for example, a sputtering method or CVD method.

Next, the pinning layer 176 is patterned using a photolithography technique and an etching technique to form an opening 178 at a portion corresponding to a region where the opening 236 is to be formed. In this case, the opening 178 is formed to have an opening width larger than that of the opening 236 so that the entire opening 236 is positioned inside the opening 178 even when the maximum alignment deviation occurs in the opening 236 in consideration of the alignment tolerance at the time of forming the opening 236.

Next, after an insulating material such as silicon oxide is deposited by, for example, CVD method, the surface thereof is planarized by, for example, CMP method to form an insulating layer 232 made of silicon oxide or the like. An interconnection layer may be provided in the insulating layer 232 as required.

Next, a photoresist (not illustrated) having an opening in a region where the opening 236 is to be formed is formed by photolithography. Next, the insulating layer 232, the first substrate 110, and the insulating layer 166 are sequentially etched using the photoresist as a mask to form the opening 236 reaching the interconnection 170. At this time, the region where the opening 236 is to be formed is located inside the opening 178 of the pinning layer 176, and it is not necessary to remove the pinning layer 176 in the process of forming the opening 236. Thereafter, the photoresist used as the mask is removed (FIG. 14).

Next, an insulating material such as silicon oxide is deposited by, e.g., CVD method, the surface thereof is planarized by, e.g., CMP method, and the opening 236 is filled with an insulating layer 238 made of silicon oxide or the like.

Next, the insulating layer 238 is patterned using a photolithography technique and an etching technique, and an opening 240 reaching the interconnection 170 is formed in the insulating layer 238. At this time, the opening 240 is provided so as to penetrate the central portion of the insulating layer 238 in a plan view, and the insulating layer 238 remains as it is in the inner wall portion of the opening 236.

Next, after a conductive material such as polycrystalline silicon or metal is deposited by, for example, a sputtering method or CVD method, the surface thereof is planarized by, for example, CMP method to form a through electrode 242 filled in the opening 240 (FIG. 15).

Next, an insulating material such as silicon oxide is deposited by, e.g., CVD to form an insulating layer 244 made of silicon oxide or the like.

Next, by using, for example, a damascene method, an interconnection layer including interconnections 248 connected to the through electrode 242 and the interconnections 234 via the interconnection vias 246 is formed in the insulating layer 244 (see FIG. 13).

By forming the opening 178 in the pinning layer 176 in advance, in the step of forming the opening 236, as illustrated in FIG. 14, the opening 236 reaching the interconnection 170 may be formed without etching the pinning layer 176. Therefore, also in the photoelectric conversion device 100 according to the present embodiment, the photoresist used for forming the opening 236 may be made thin, and the peeling process in the subsequent step is facilitated. In addition, the opening area of the opening 236 may be easily reduced.

As described above, according to the present embodiment, in the photoelectric conversion device including the through electrode connected to the interconnection through the semiconductor substrate, the process of forming the opening penetrating the semiconductor substrate from the back surface side may be facilitated.

### Third Embodiment

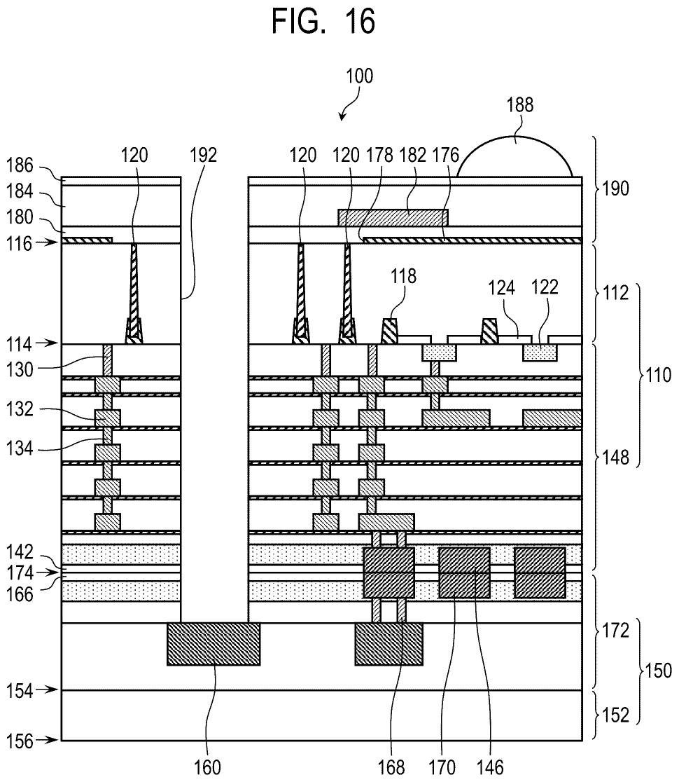

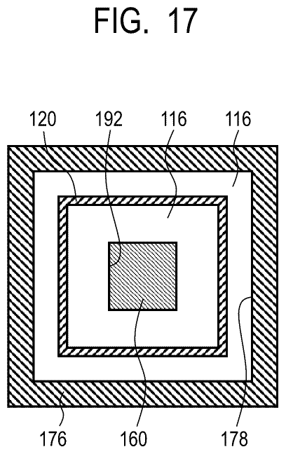

A photoelectric conversion device according to a third embodiment of the present invention will be described with reference to FIG. 16 and FIG. 17. The same components as those of the photoelectric conversion device according to the first or second embodiment are denoted by the same reference numerals, and description thereof will be omitted or simplified. FIG. 16 is a schematic cross-sectional view illustrating the structure of the photoelectric conversion device according to the present embodiment. FIG. 17 is a plan view of the periphery of the pad opening of the photoelectric conversion device according to the present embodiment.

The photoelectric conversion device 100 according to the present embodiment is the same as the photoelectric conversion device according to the first embodiment except that the size of the opening 178 provided in the pinning layer 176 is different. That is, in the first embodiment, as illustrated in FIG. 3 and FIG. 4, the opening 178 is disposed so that the opening 178 is located inside the isolation structures 118 and 120 surrounding the pad opening 192 in the plan view. In contrast, in the present embodiment, as illustrated in FIG. 16 and FIG. 17, the opening 178 is disposed so that the isolation structures 118 and 120 surrounding the pad opening 192 are located inside the opening 178 in the plan view.

By disposing the isolation structures 118 and 120 surrounding the pad opening 192 inside the opening 178, a part of the second face 116 of the semiconductor substrate 112 on the pixel region 10 is covered with the insulating layer 180 instead of the pinning layer 176. In this case, for example, by using a hydrogen storage film as the insulating layer 180, hydrogen is supplied to the semiconductor substrate 112 from a portion where the insulating layer 180 and the second face 116 are in contact with each other, and hydrogen termination of dangling bonds at the interface of the semiconductor substrate 112 is performed. Accordingly, since the interface state density of the semiconductor substrate 112 is reduced, improvement in signal quality of the photoelectric conversion device may be expected.

As described above, according to the present embodiment, in the photoelectric conversion device including the pad opening penetrating the semiconductor substrate and reaching the electrode pad, the process of forming the opening penetrating the semiconductor substrate from the back surface side may be facilitated. Further, the signal quality of the photoelectric conversion device may be improved.

### Fourth Embodiment

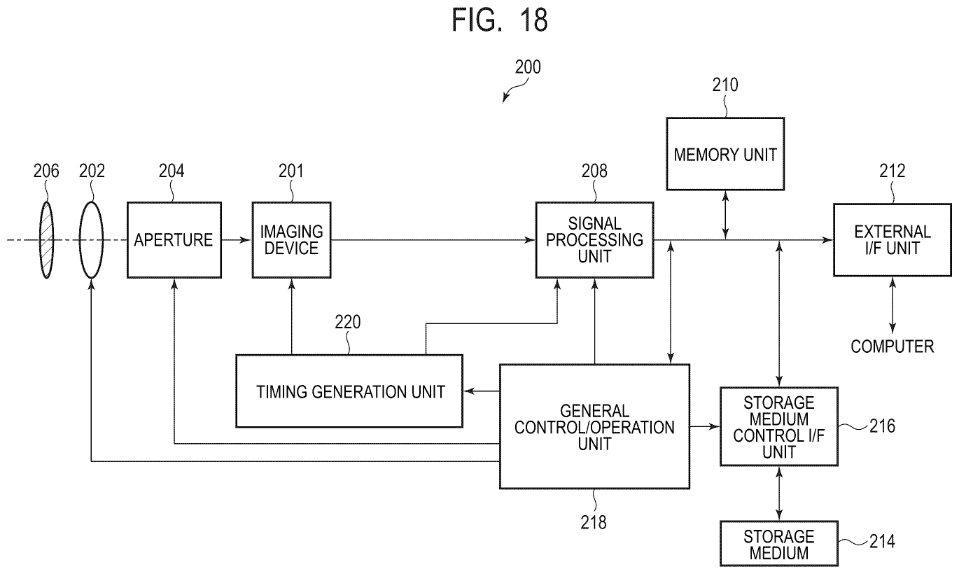

A photoelectric conversion system according to a fourth embodiment of the present invention will be described with reference to FIG. 18. FIG. 18 is a block diagram illustrating a schematic configuration of a photoelectric conversion system according to the present embodiment.

The photoelectric conversion device 100 described in the first to third embodiments may be applied to various photoelectric conversion systems. Examples of applicable photoelectric conversion systems include digital still cameras, digital camcorders, surveillance cameras, copying machines, facsimiles, mobile phones, on-vehicle cameras, observation satellites, and the like. A camera module including an optical system such as a lens and an imaging device is also included in the photoelectric conversion system. FIG. 18 exemplifies a block diagram of a digital still camera as one of these.

The photoelectric conversion system 200 illustrated in FIG. 18 includes an imaging device 201, a lens 202 that forms an optical image of an object on the imaging device 201, an aperture 204 that changes the amount of light passing through the lens 202, and a barrier 206 that protects the lens 202. The lens 202 and the aperture 204 form an optical system that focuses light onto the imaging device 201. The imaging device 201 is the photoelectric conversion device 100 described in any of the first to third embodiments, and converts the optical image formed by the lens 202 into image data.

The photoelectric conversion system 200 further includes a signal processing unit 208 that processes an output signal output from the imaging device 201. The signal processing unit 208 generates image data from the digital signal output from the imaging device 201. Further, the signal processing unit 208 performs various corrections and compressions as necessary and outputs the processed image data. The imaging device 201 may include an AD conversion unit that generates a digital signal to be processed by the signal processing unit 208. The AD conversion unit may be formed on a semiconductor layer (semiconductor substrate) on which the photoelectric conversion unit of the imaging device 201 is formed or may be formed on a semiconductor layer different from the semiconductor layer on which the photoelectric conversion unit of the imaging device 201 is formed. In addition, the signal processing unit 208 may be formed on the same semiconductor layer as the imaging device 201.

The photoelectric conversion system 200 further includes a memory unit 210 for temporarily storing image data and an external interface unit (external I/F unit) 212 for communicating with an external computer or the like. The photoelectric conversion system 200 further includes a storage medium 214 such as a semiconductor memory for performing storing or reading out of imaging data, and a storage medium control interface unit (storage medium control I/F unit) 216 for performing storing on or reading out from the storage medium 214. The storage medium 214 may be built in the photoelectric conversion system 200 or may be detachable.

The photoelectric conversion system 200 further includes a general control/operation unit 218 that performs various calculations and controls the entire digital still camera, and a timing generation unit 220 that outputs various timing signals to the imaging device 201 and the signal processing unit 208. Here, the timing signal or the like may be input from the outside, and the photoelectric conversion system 200 may include at least the imaging device 201 and the signal processing unit 208 that processes the output signal output from the imaging device 201.

The imaging device 201 outputs an imaging signal to the signal processing unit 208. The signal processing unit 208 performs predetermined signal processing on the imaging signal output from the imaging device 201, and outputs the processed image data. The signal processing unit 208 generates an image using the imaging signal.

As described above, according to the present embodiment, it is possible to realize a photoelectric conversion system to which the photoelectric conversion device 100 according to any of the first to third embodiments is applied.

### Fifth Embodiment

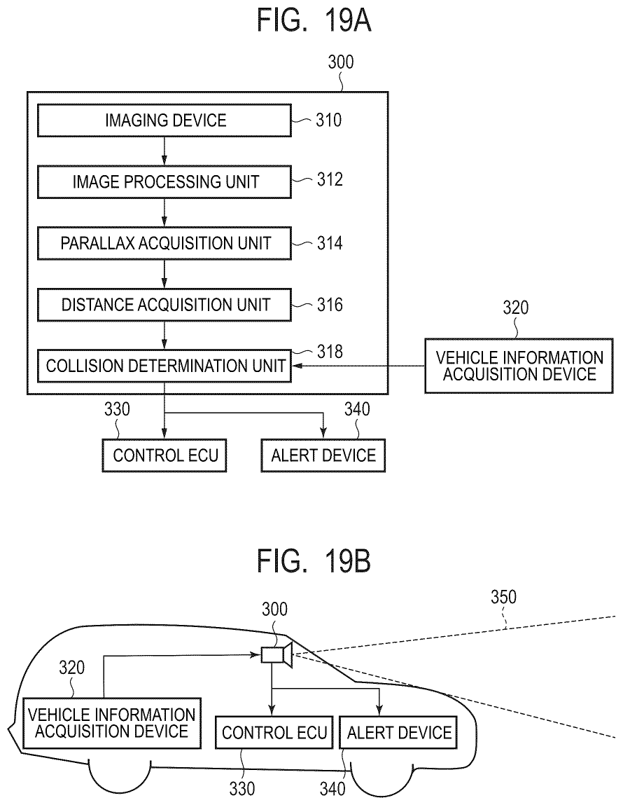

A photoelectric conversion system and a movable object according to a fifth embodiment of the present invention will be described with reference to FIG. 19A and FIG. 19B. FIG. 19A is a diagram illustrating a configuration of a photoelectric conversion system according to the present embodiment. FIG. 19B is a diagram illustrating a configuration of a movable object according to the present embodiment.

FIG. 19A illustrates an example of a photoelectric conversion system related to an on-vehicle camera. The photoelectric conversion system 300 includes an imaging device 310. The imaging device 310 is the photoelectric conversion device 100 according to any one of the first to third embodiments. The photoelectric conversion system 300 includes an image processing unit 312 that performs image processing on a plurality of image data acquired by the imaging device 310, and a parallax acquisition unit 314 that calculates parallax (phase difference of parallax images) from the plurality of image data acquired by the imaging device 310. The photoelectric conversion system 300 further includes a distance acquisition unit 316 that calculates a distance to an object based on the calculated parallax, and a collision determination unit 318 that determines whether there is a collision possibility based on the calculated distance. Here, the parallax acquisition unit 314 and the distance acquisition unit 316 are examples of a distance information acquisition unit that acquires distance information to the object. That is, the distance information is information related to a parallax, a defocus amount, a distance to the object, and the like. The collision determination unit 318 may determine the collision possibility using any of the distance information. The distance information acquisition unit may be realized by dedicatedly designed hardware or may be realized by a software module. Further, it may be realized by a field programmable gate array (FPGA), an application specific integrated circuit (ASIC), or the like, or may be realized by a combination of these.

The photoelectric conversion system 300 is connected to the vehicle information acquisition device 320 and may acquire vehicle information such as a vehicle speed, a yaw rate, and a steering angle. Further, the photoelectric conversion system 300 is connected to a control ECU 330 which is a control device that outputs a control signal for generating a braking force to the vehicle based on the determination result of the collision determination unit 318. The photoelectric conversion system 300 is also connected to an alert device 340 that issues an alert to the driver based on the determination result of the collision determination unit 318. For example, when the determination result of the collision determination unit 318 indicates that the possibility of collision is high, the control ECU 330 performs vehicle control to avoid collision and reduce damage by, for example, applying a brake, returning an accelerator, or suppressing engine output. The alert device 340 gives an alert to the user by sounding an alarm such as a sound, displaying alert information on a screen of a car navigation system or the like, giving vibration to a seat belt or a steering wheel, or the like.

In the present embodiment, an image of the surroundings of the vehicle, for example, the front or the rear is captured by the photoelectric conversion system 300. FIG. 19B illustrates the photoelectric conversion system in the case of capturing an image in front of the vehicle (imaging range 350). The vehicle information acquisition device 320 sends an instruction to the photoelectric conversion system 300 or the imaging device 310. With such a configuration, the accuracy of distance measurement may be further improved.

Although an example in which control is performed so as not to collide with another vehicle has been described above, the present invention is also applicable to control in which automatic driving is performed so as to follow another vehicle, control in which automatic driving is performed so as not to protrude from a lane, and the like. Further, the photoelectric conversion system is not limited to a vehicle such as an own vehicle, and may be applied to, for example, other movable object (mobile device) of a ship, an aircraft, or an industrial robot. In addition, the present invention is not limited to the movable object and may be widely applied to equipment using object recognition, such as intelligent transport systems (ITS).

### Sixth Embodiment

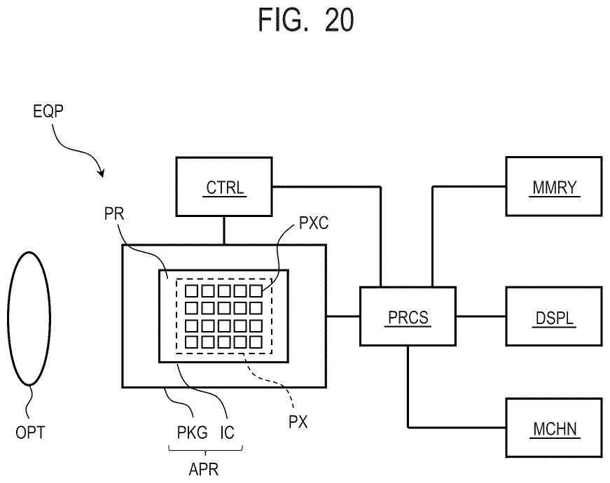

An equipment according to a sixth embodiment of the present invention will be described with reference to FIG. 20. FIG. 20 is a block diagram illustrating a schematic configuration of an equipment according to the present embodiment.

FIG. 20 is a schematic diagram illustrating an equipment EQP including a photoelectric conversion device APR. The photoelectric conversion device APR has the function of the photoelectric conversion device 100 according to any of the first to third embodiments. All or part of the photoelectric conversion device APR is a semiconductor device IC. The photoelectric conversion device APR of the present example may be used as, for example, an image sensor, an AF (Auto Focus) sensor, a photometric sensor, or a distance measurement sensor. The semiconductor device IC includes a pixel region PX in which pixel circuits PXC each including a photoelectric conversion unit are arranged in a matrix. The semiconductor device IC may include a peripheral region PR around the pixel region PX. A circuit other than the pixel circuit may be disposed in the peripheral region PR.

The photoelectric conversion device APR may have a structure (chip stacked structure) in which a first semiconductor chip provided with a plurality of photoelectric conversion units and a second semiconductor chip provided with peripheral circuits are stacked. Each of the peripheral circuits in the second semiconductor chip may be column circuits corresponding to pixel columns of the first semiconductor chip. The peripheral circuits in the second semiconductor chip may be matrix circuits corresponding to pixels or pixel blocks in the first semiconductor chip. As the connection between the first semiconductor chip and the second semiconductor chip, a through electrode (through silicon via (TSV)), an inter-chip interconnection by direct bonding of a conductor such as copper, a connection by a micro bump between chips, a connection by wire bonding, or the like may be employed.

The photoelectric conversion device APR may include a package PKG that accommodates the semiconductor device IC in addition to the semiconductor device IC. The package PKG may include a base body to which the semiconductor device IC is fixed, a lid body such as glass facing the semiconductor device IC, and connection members such as bonding wires or bumps for connecting terminals provided on the base body and terminals provided on the semiconductor device IC.

The equipment EQP may further include at least one of an optical device OPT, a control device CTRL, a processing device PRCS, a display device DSPL, a storage device MMRY, and a mechanical device MCHN. The optical device OPT corresponds to the photoelectric conversion device APR as a photoelectric conversion device, and is, for example, a lens, a shutter, or a mirror. The control device CTRL controls the photoelectric conversion device APR, and is, for example, a semiconductor device such as an ASIC. The processing device PRCS processes a signal output from the photoelectric conversion device APR and constitutes an analog front end (AFE) or a digital front end (DFE). The processing unit PRCS is a semiconductor device such as a central processing unit (CPU) or an ASIC. The display device DSPL may be an electroluminescent (EL) display device or a liquid crystal display device that displays information (image) obtained by the photoelectric conversion device APR. The storage device MMRY may be a magnetic device or a semiconductor device that stores information (image) obtained by the photoelectric conversion device APR. The storage device MMRY may be a volatile memory such as an SRAM or a DRAM, or a nonvolatile memory such as a flash memory or a hard disk drive. The mechanical device MCHN may include a movable portion or a propulsion portion such as a motor or an engine. In the equipment EQP, a signal output from the photoelectric conversion device APR is displayed on the display device DSPL or transmitted to the outside by a communication device (not illustrated) included in the equipment EQP. Therefore, it is preferable that the equipment EQP further includes a storage device MMRY and a processing device PRCS separately from the storage circuit unit and the arithmetic circuit unit included in the photoelectric conversion device APR.

The equipment EQP illustrated in FIG. 20 may be an electronic device such as an information terminal (for example, a smartphone or a wearable terminal) having a photographing function or a camera (for example, an interchangeable lens camera, a compact camera, a video camera, and a monitoring camera. The mechanical device MCHN in the camera may drive components of the optical device OPT for zooming, focusing, and shutter operation. The equipment EQP may be a transportation device (movable object) such as a vehicle, a ship, or an airplane. The equipment EQP may be a medical device such as an endoscope or a CT scanner.

The mechanical device MCHN in the transport device may be used as a mobile device. The equipment EQP as a transport device is suitable for transporting the photoelectric conversion device APR, or for assisting and/or automating operation (manipulation) by an imaging function. The processing device PRCS for assisting and/or automating driving (manipulation) may perform processing for operating the mechanical device MCHN as a mobile device based on information obtained by the photoelectric conversion device APR.

The photoelectric conversion device APR according to the present embodiment may provide a high value to a designer, a manufacturer, a seller, a purchaser, and/or a user thereof. Therefore, when the photoelectric conversion device APR is mounted on the equipment EQP, the value of the equipment EQP may also be increased. Therefore, in manufacturing and selling the equipment EQP, it is advantageous to determine the mounting of the photoelectric conversion device APR of the present embodiment on the equipment EQP in order to increase the value of the equipment EQP.

### Modified Embodiments

The present invention is not limited to the above-described embodiment, and various modifications are possible.

For example, an example in which a part of the configuration of any of the embodiments is added to another embodiment or an example in which a part of the configurations of any of the embodiments is substituted with some of the configurations of another embodiment is also an embodiment of the present invention.

In the first to third embodiments, an example in which the present invention is applied to a back-illuminated photoelectric conversion device has been described, but the present invention may be widely applied to a photoelectric conversion device having an opening provided through a pinning layer.

In the first to third embodiments, a stacked-type photoelectric conversion device in which a substrate provided with pixels and a substrate provided with a drive circuit are stacked has been described, but the configuration of the substrate constituting the photoelectric conversion device is not limited to the example of the above-described embodiments. For example, the second substrate 150 may be used as a support substrate, and all functional blocks constituting the photoelectric conversion device may be disposed on the first substrate 110. Alternatively, a stacked-type photoelectric conversion device in which three or more substrates are stacked may be configured.

In the first to third embodiments, the interconnection 170 to which the electrode pad 160 or the through electrode 242 is connected is disposed on the second substrate 150 side, but the interconnection to which the electrode pad or the through electrode is connected may be disposed on the first substrate 110 side (interconnection structure layer 148).

The photoelectric conversion systems described in the fourth and fifth embodiments are examples of photoelectric conversion systems to which the photoelectric conversion device of the present invention may be applied, and the photoelectric conversion system to which the photoelectric conversion device of the present invention may be applied is not limited to the configuration illustrated in FIG. 18 and FIG. 19A.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2024-021144, filed Feb. 15, 2024, which is hereby incorporated by reference herein in its entirety.

What is claimed is:

1. A method of manufacturing a photoelectric conversion device comprising:
forming a photoelectric conversion unit in a first substrate;
forming a first interconnection on a side of a first face of the first substrate;
forming a pinning layer on a second face of the first substrate that is a light receiving face of the photoelectric conversion unit;
forming a first opening in the pinning layer;
forming an insulating layer on the pinning layer and in the first opening; and
forming, in a region inside the first opening in a plan view, a second opening that penetrates the insulating layer and the first substrate and reaches the first interconnection.

2. The method of manufacturing a photoelectric conversion device according to claim 1,
wherein the first interconnection is an electrode pad, and
wherein the second opening is a pad opening reaching the electrode pad.

3. The method of manufacturing a photoelectric conversion device according to claim 1 further comprising:
forming, in the second opening, a through electrode that is insulated from the first substrate and electrically connected to the first interconnection; and
forming, over the insulating layer, a second interconnection electrically connected to the through electrode.

4. The method of manufacturing a photoelectric conversion device according to claim 1 further comprising: forming a first interconnection structure layer on the side of the first face of the first substrate.

5. The method of manufacturing a photoelectric conversion device according to claim 4, wherein the forming the first interconnection structure layer includes the forming the first interconnection.

6. The method of manufacturing a photoelectric conversion device according to claim 1 further comprising: bonding a second substrate including a second interconnection structure layer to the side of the first face of the first substrate.

7. The method of manufacturing a photoelectric conversion device according to claim 6, wherein the second interconnection structure layer includes the first interconnection.

8. The method of manufacturing a photoelectric conversion device according to claim 1 further comprising: forming an isolation structure in the first substrate, wherein the isolation structure is disposed so as to surround the first opening in the plan view.

9. The method of manufacturing a photoelectric conversion device according to claim 8, wherein the isolation structure is disposed so as to surround the second opening in the plan view.

10. The method of manufacturing a photoelectric conversion device according to claim 8, wherein the isolation structure is disposed inside the second opening in the plan view.

11. A photoelectric conversion device comprising:
a first substrate having a first face and a second face and provided with a photoelectric conversion unit with the second face as a light receiving surface;
a first interconnection provided on a side of the first face of the first substrate;
a pinning layer provided on the second face of the first substrate and having a first opening;
an insulating layer provided on the pinning layer and in the first opening; and
a second opening that is provided in a region inside the first opening in a plan view, penetrates the insulating layer and the first substrate, and reaches the first interconnection.

12. The photoelectric conversion device according to claim 11, wherein the pinning layer is not exposed to the second opening.

13. The photoelectric conversion device according to claim 11,
wherein the first interconnection is an electrode pad, and
the second opening is a pad opening reaching the electrode pad.

14. The photoelectric conversion device according to claim 11 further comprising:
a through electrode provided in the second opening, insulated from the first substrate, and electrically connected to the first interconnection; and
a second interconnection provided over the insulating layer and electrically connected to the through electrode.

15. The photoelectric conversion device according to claim 11 further comprising: a first interconnection structure layer provided on the side of the first face of the first substrate.

16. The photoelectric conversion device according to claim 15, wherein the first interconnection structure layer includes the first interconnection.

17. The photoelectric conversion device according to claim 11 further comprising: a second substrate bonded to the side of the first face of the first substrate and including a second interconnection structure layer.

18. The photoelectric conversion device according to claim 17, wherein the second interconnection structure layer includes the first interconnection.

19. The photoelectric conversion device according to claim 11 further comprising: an isolation structure provided in the first substrate, wherein the isolation structure is disposed so as to surround the first opening in the plan view.

20. The photoelectric conversion device according to claim 19, wherein the isolation structure is disposed so as to surround the second opening in the plan view.

21. The photoelectric conversion device according to claim 19, wherein the isolation structure is disposed inside the second opening in the plan view.

22. The photoelectric conversion device according to claim 19, wherein the pinning layer includes an aluminum oxide film and/or a tantalum oxide film.

23. A photoelectric conversion system comprising:
the photoelectric conversion device according to claim 11; and
a signal processing device configured to process a signal output from the photoelectric conversion device.

24. A movable object comprising:
the photoelectric conversion device according to claim 11;
a distance information acquisition unit configured to acquire distance information to an object from a parallax image based on a signal from the photoelectric conversion device; and
a control unit configured to control the movable object based on the distance information.

25. An equipment comprising:
the photoelectric conversion device according to claim 11; and
at least one of
an optical device corresponding to the photoelectric conversion device,
a control device configured to control the photoelectric conversion device,
a processing device configured to process a signal output from the photoelectric conversion device,
a mechanical device that is controlled based on information obtained by the photoelectric conversion device,
a display device configured to display information obtained by the photoelectric conversion device, and
a storage device configured to store information obtained by the photoelectric conversion device.
